(19) United States
(12) Patent Application Publication
(10) Pub. No.: US 2026/0123201 A1
(43) Pub. Date: Apr. 30, 2026

(54) DISPLAY DEVICE

(71) Applicant: Sharp Kabushiki Kaisha, Osaka (JP)

(72) Inventors: Kengo HARA, Sakai City (JP); Hajime IMAI, Sakai City (JP); Yoshihito HARA, Sakai City (JP); Masaki MAEDA, Sakai City (JP); Jun NISHIMURA, Sakai City (JP); Yoshiharu HIRATA, Sakai City (JP); Hideki KITAGAWA, Sakai City (JP)

(21) Appl. No.: 19/365,298

(22) Filed: Oct. 22, 2025

(30) Foreign Application Priority Data
Oct. 28, 2024 (JP) 2024-189025

(51) Int. Cl. H10K 59/124; H10K 59/121; H10K 59/131

(52) U.S. Cl. CPC H10K 59/124; H10K 59/1213; H10K 59/131

(57) ABSTRACT

A display device includes: a thin film transistor layer and a light-emitting element layer. A terminal portion is provided with a first terminal layer formed of a second metal film, a first protection layer and a second protection layer formed of a second inorganic insulating film and a third inorganic insulating film are provided on the first terminal layer so as to expose a part of the first terminal layer and cover the other part of the first terminal layer, and a second terminal layer formed in the same layer and formed of the same material as each of transparent electrodes is provided on the first terminal layer exposed from the first protection layer and the second protection layer so as to cover the first terminal layer.

### CROSS-REFERENCE TO RELATED APPLICATIONS

This application claims the benefit of priority to Japanese Patent Application Number 2024-189025 filed on Oct. 28, 2024. The entire contents of the above-identified application are hereby incorporated by reference.

### BACKGROUND

### Technical Field

The disclosure relates to a display device.

In recent years, as a display device replacing a liquid crystal display device, a self-luminous organic electroluminescence (hereinafter also referred to as “EL”) display device using an organic EL element has attracted attention. The organic EL display device includes, for example, a base substrate, a TFT layer in which a thin film transistor (hereinafter also referred to as “TFT”) provided on the base substrate is disposed, an organic EL element layer which is provided on the TFT layer and has a plurality of organic EL elements disposed corresponding to a plurality of subpixels, and a sealing film provided on the organic EL element layer. Here, the organic EL element includes, for example, a pixel electrode provided as an anode on the TFT layer, an organic EL layer provided on the pixel electrode, and a common electrode provided as a cathode on the organic EL layer. The organic EL display device also includes a display region in which a plurality of subpixels are disposed, and a frame region provided around the display region. Note that the display region includes display wiring line such as gate lines and source lines, the display wiring line are led out to the ends of the frame region, and terminal portions for connection to external circuits and the like are provided in the ends of the frame region.

For example, JP 2008-41277 A discloses a terminal structure in which a reflective layer is provided to cover a wiring line layer in a wiring line terminal portion, and a transparent anode electrode is provided to cover the reflective layer.

### SUMMARY

Incidentally, in the organic EL display device having the terminal structure disclosed in JP 2008-41277 A described above, the reflective layer configured with, for example, a silver film or the like is also provided in the terminal portion. Thus, even when the reflective layer is covered with a transparent anode electrode, there is a concern of the reflective layer corroding, and thus there is room for improvement.

The disclosure has been made in view of the above-described circumstances, and an object thereof is to curb corrosion of a terminal portion.

In order to achieve the above object, a display device according to the disclosure includes a base substrate, a thin film transistor layer provided on the base substrate and configured such that a first metal film, a first inorganic insulating film, a first organic insulating film, a second metal film, a second inorganic insulating film, and a second organic insulating film are sequentially layered, and a light-emitting element layer provided on the thin film transistor layer and configured such that a plurality of reflective electrodes, a common third inorganic insulating film, a plurality of transparent electrodes, a plurality of light-emitting function layers, and a common light-transmissive electrode are sequentially layered to correspond to a plurality of subpixels configuring a display region, the third inorganic insulating film being provided to cover circumferential end portions of the reflective electrodes, a frame region being provided around the display region, and a terminal portion being provided at an end of the frame region, in which the terminal portion is provided with a first terminal layer formed of the second metal film, a first protection layer and a second protection layer formed of the second inorganic insulating film and the third inorganic insulating film are provided on the first terminal layer so as to expose a part of the first terminal layer and cover the other part of the first terminal layer, and a second terminal layer formed in the same layer and formed of the same material as each of the transparent electrodes is provided on the first terminal layer exposed from the first protection layer and the second protection layer so as to cover the first terminal layer.

According to the disclosure, it is possible to curb corrosion of a terminal portion.

### BRIEF DESCRIPTION OF DRAWINGS

The disclosure will be described with reference to the accompanying drawings, wherein like numbers reference like elements.

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is a cross-sectional view of a terminal portion of the organic EL display device according to the first embodiment of the disclosure.

FIG. 5 is an equivalent circuit diagram of a TFT layer configuring the organic EL display device according to the first embodiment of the disclosure.

FIG. 6 is a cross-sectional view illustrating an organic EL layer configuring the organic EL display device according to the first embodiment of the disclosure.

FIG. 7 is a first cross-sectional view illustrating a part of a manufacturing process in the display region of the organic EL display device according to the first embodiment of the disclosure, and is a diagram corresponding to FIG. 3.

FIG. 8 is a second cross-sectional view continuing from FIG. 7 illustrating a part of the manufacturing process in the display region of the organic EL display device according to the first embodiment of the disclosure, and is a diagram corresponding to FIG. 3.

FIG. 9 is a third cross-sectional view continuing from FIG. 8 illustrating a part of the manufacturing process in the display region of an organic EL display device according to the first embodiment of the disclosure, and is a diagram corresponding to FIG. 3.

FIG. 10 is a fourth cross-sectional view continuing from FIG. 9 illustrating a part of the manufacturing process in the display region of the organic EL display device according to the first embodiment of the disclosure, and is a diagram corresponding to FIG. 3.

FIG. 11 is a fifth cross-sectional view continuing from FIG. 10 illustrating a part of the manufacturing process in the display region of the organic EL display device according to the first embodiment of the disclosure, and is a diagram corresponding to FIG. 3.

FIG. 12 is a sixth cross-sectional view continuing from FIG. 11 illustrating a part of the manufacturing process in the display region of the organic EL display device according to the first embodiment of the disclosure, and is a diagram corresponding to FIG. 3.

FIG. 13 is a seventh cross-sectional view continuing from FIG. 12 illustrating a part of the manufacturing process in the display region of the organic EL display device according to the first embodiment of the disclosure, and is a diagram corresponding to FIG. 3.

FIG. 14 is an eighth cross-sectional view continuing from FIG. 13 illustrating a part of the manufacturing process in the display region of the organic EL display device according to the first embodiment of the disclosure, and is a diagram corresponding to FIG. 3.

FIG. 15 is a ninth cross-sectional view continuing from FIG. 14 illustrating a part of the manufacturing process in the display region of the organic EL display device according to the first embodiment of the disclosure, and is a diagram corresponding to FIG. 3.

FIG. 16 is a tenth cross-sectional view continuing from FIG. 15 illustrating a part of the manufacturing process in the display region of the organic EL display device according to the first embodiment of the disclosure, and is a diagram corresponding to FIG. 3.

FIG. 17 is an eleventh cross-sectional view continuing from FIG. 16 illustrating a part of the manufacturing process in the display region of the organic EL display device according to the first embodiment of the disclosure, and is a diagram corresponding to FIG. 3.

FIG. 18 is a first cross-sectional view illustrating a part of the manufacturing process in the terminal portion of the organic EL display device according to the first embodiment of the disclosure, and is a diagram corresponding to FIG. 4.

FIG. 19 is a second cross-sectional view continuing from FIG. 18 illustrating a part of the manufacturing process in the terminal portion of the organic EL display device according to the first embodiment of the disclosure, and is a diagram corresponding to FIG. 4.

FIG. 20 is a third cross-sectional view continuing from FIG. 19 illustrating a part of the manufacturing process in the terminal portion of the organic EL display device according to the first embodiment of the disclosure, and is a diagram corresponding to FIG. 4.

FIG. 21 is a fourth cross-sectional view continuing from FIG. 20 illustrating a part of the manufacturing process in the terminal portion of the organic EL display device according to the first embodiment of the disclosure, and is a diagram corresponding to FIG. 4.

FIG. 22 is a fifth cross-sectional view continuing from FIG. 21 illustrating a part of the manufacturing process in the terminal portion of the organic EL display device according to the first embodiment of the disclosure, and is a diagram corresponding to FIG. 4.

FIG. 23 is a sixth cross-sectional view continuing from FIG. 22 illustrating a part of the manufacturing process in the terminal portion of the organic EL display device according to the first embodiment of the disclosure, and is a diagram corresponding to FIG. 4.

FIG. 24 is a seventh cross-sectional view continuing from FIG. 23 illustrating a part of the manufacturing process in the terminal portion of the organic EL display device according to the first embodiment of the disclosure, and is a diagram corresponding to FIG. 4.

FIG. 25 is an eighth cross-sectional view continuing from FIG. 24 illustrating a part of the manufacturing process in the terminal portion of the organic EL display device according to the first embodiment of the disclosure, and is a diagram corresponding to FIG. 4.

FIG. 26 is a ninth cross-sectional view continuing from FIG. 25 illustrating a part of the manufacturing process in the terminal portion of the organic EL display device according to the first embodiment of the disclosure, and is a diagram corresponding to FIG. 4.

### DESCRIPTION OF EMBODIMENTS

Embodiments of the disclosure will be described below in detail with reference to the drawings. Note that the disclosure is not limited to the embodiments to be described below.

### First Embodiment

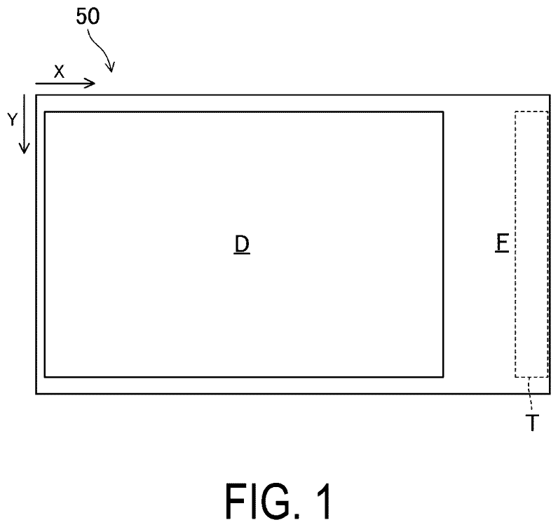

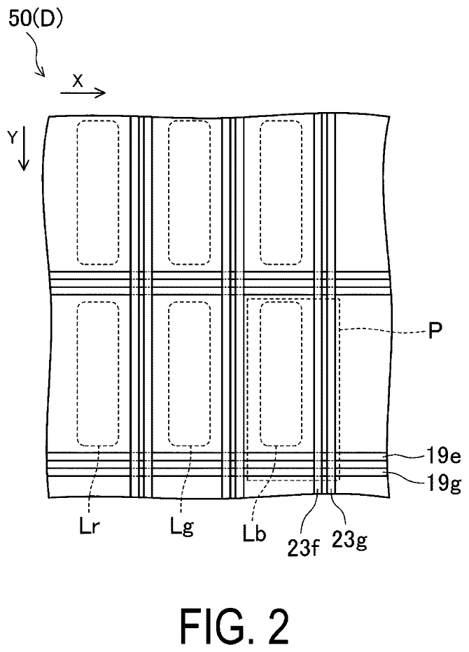

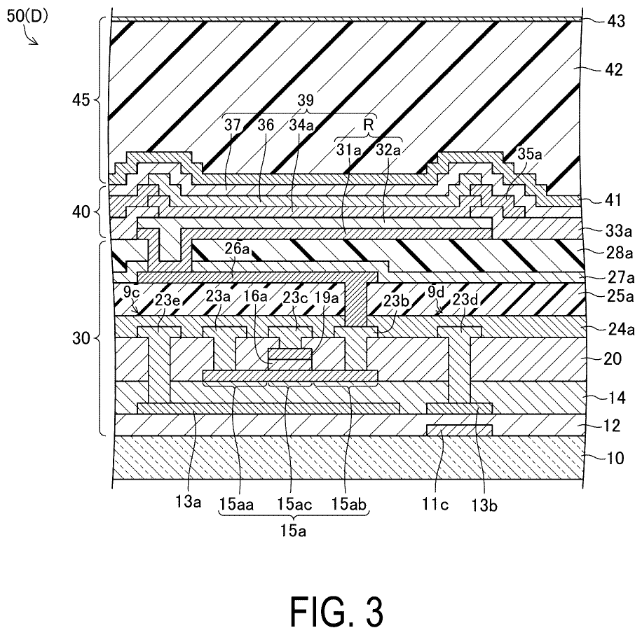

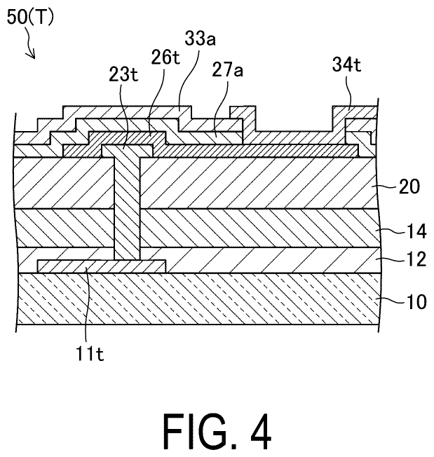

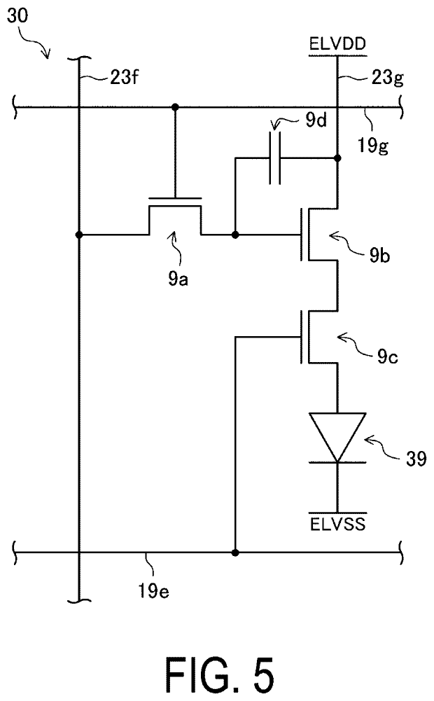

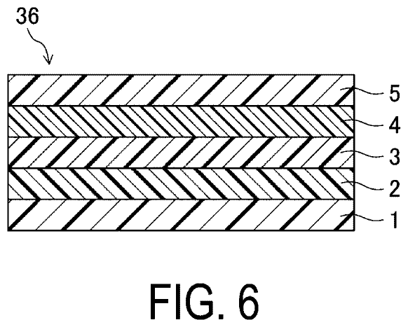

FIG. 1 to FIG. 26 illustrate a first embodiment of a display device according to the disclosure. Note that, in the following embodiment, an organic EL display device including an organic EL element layer is exemplified as a display device including a light-emitting element layer. Here, FIG. 1 is a plan view illustrating a schematic configuration of an organic EL display device 50 according to the present embodiment. In addition, FIG. 2 and FIG. 3 are a plan view and a cross-sectional view, respectively, of a display region D in the organic EL display device 50. In addition, FIG. 4 is a cross-sectional view of a terminal portion T of the organic EL display device 50. Further, FIG. 5 is an equivalent circuit diagram of a TFT layer 30 configuring the organic EL display device 50. Further, FIG. 6 is a cross-sectional view illustrating an organic EL layer 36 configuring the organic EL display device 50.

As illustrated in FIG. 1, the organic EL display device 50 includes, for example, a display region D that is provided in a rectangular shape to display an image, and a frame region F provided in a frame shape around the display region D. Note that, in the present embodiment, the display region D having a rectangular shape is illustrated, but the rectangular shape includes a substantially rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. Further, in the display region D, as illustrated in FIG. 2, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another. Note that one pixel is configured by, for example, three adjacent subpixels P including the red light-emitting region Lr, the green light-emitting region Lg, and the blue light-emitting region Lb in the display region D.

The terminal portion T is provided at a positive end of the frame region F in an X direction in FIG. 1 so as to extend in one direction (a Y direction in FIG. 1). Here, in the organic EL display device 50, display wiring line such as gate lines 19g, light emission control lines 19e, source lines 23f, and power supply lines 23g, which are provided in the display region D and will be described later, are led out toward the terminal portion T.

As illustrated in FIG. 3, the organic EL display device 50 includes a glass substrate 10 provided as a base substrate, the TFT layer 30 provided on the glass substrate 10, an organic EL element layer 40 provided on the TFT layer 30 as a light-emitting element layer, and a sealing film 45 provided on the organic EL element layer 40.

The glass substrate 10 is configured to have a thickness of, for example, approximately 0.1 mm to 0.5 mm.

As illustrated in FIG. 3, the TFT layer 30 includes a plurality of first TFTs 9a (see FIG. 5), a plurality of second TFTs 9b (see FIG. 5), a plurality of third TFTs 9c, and a plurality of capacitors 9d which are provided on the glass substrate 10, and a protection insulating film 24a, a first flattening film 25a, a first protection layer 27a, and a second flattening film 28a provided sequentially on each of the first TFTs 9a, each of the second TFTs 9b, each of the third TFTs 9c, and each of the capacitors 9d.

In the TFT layer 30, as illustrated in FIG. 3, a third metal film that serves as a first capacitance electrode 11c to be described later, a base insulating film (fourth inorganic insulating film) 12, a fourth metal film that serves as a first gate electrode 13a to be described later, a first gate insulating film (fifth inorganic insulating film) 14, a semiconductor film that serves as a semiconductor layer 15a to be described later, a second gate insulating film (sixth inorganic insulating film) 16a, a fifth metal film that serves as a second gate electrode 19a to be described later, an interlayer insulating film (seventh inorganic insulating film) 20, a first metal film that serves as a source electrode 23a to be described later, a protection insulating film (first inorganic insulating film) 24a, a first flattening film (first organic insulating film) 25a, a second metal film that serves as a relay electrode 26a to be described later, a first protection layer (second inorganic insulating film) 27a, and a second flattening film (second organic insulating film) 28a are sequentially layered on the glass substrate 10. Here, the base insulating film 12, the first gate insulating film 14, the second gate insulating film 16a, the interlayer insulating film 20, the protection insulating film 24a, and the first protection layer 27a are configured with a single-layer or a layered film of an inorganic insulating film such as a silicon nitride film, a silicon oxide film, or a silicon oxynitride film. Note that the first gate insulating film 14 on the semiconductor layer 15a side and the second gate insulating film 16a on the semiconductor layer 15a side are configured with, for example, a silicon oxide film.

Here, as illustrated in FIG. 2, in the TFT layer 30, a plurality of gate lines 19g are provided to extend parallel to each other in the X direction in the drawing. In addition, as illustrated in FIG. 2, in the TFT layer 30, a plurality of light emission control lines 19e are provided to extend parallel to each other in the X direction in the drawing. Here, as illustrated in FIG. 2, each of the light emission control lines 19e is provided adjacent to each of the gate lines 19g. In addition, as illustrated in FIG. 2, in the TFT layer 30, a plurality of source lines 23f are provided to extend parallel to each other in the Y direction in the drawing. Further, as illustrated in FIG. 2, in the TFT layer 30, a plurality of power supply lines 23g are provided to extend parallel to each other in the Y direction in the drawing. Note that, as illustrated in FIG. 2, each of the power supply lines 23g is provided adjacent to each of the source lines 23f. Further, in the TFT layer 30, as illustrated in FIG. 5, each subpixel P includes the first TFT 9a, the second TFT 9b, the third TFT 9c, and the capacitor 9d. Here, each of the gate lines 19g and each of the light emission control lines 19e are formed of a fifth metal film, and each of the source lines 23f and each of the power supply lines 23g are formed of a first metal film.

As illustrated in FIG. 5, the first TFT 9a is electrically connected to the corresponding gate line 19g, the corresponding source line 23f, and the corresponding second TFT 9b in each subpixel P. Note that the first TFT 9a has substantially the same structure as the third TFT 9c, which will be described later.

As illustrated in FIG. 5, the second TFT 9b is electrically connected to the corresponding first TFT 9a, the corresponding power supply line 23g, and the corresponding third TFT 9c in each subpixel P. Note that the second TFT 9b has substantially the same structure as the third TFT 9c, which will be described later.

As illustrated in FIG. 5, the third TFT 9c is electrically connected to the corresponding second TFT 9b, a first electrode 31 configuring an organic EL element 39 to be described later, and the light emission control line 19e in each subpixel P. In addition, as illustrated in FIG. 3, the third TFT 9c includes the semiconductor layer 15a, the first gate electrode 13a provided on the glass substrate 10 side of the semiconductor layer 15a via the first gate insulating film 14, the second gate electrode 19a provided on the opposite side of the semiconductor layer 15a to the glass substrate 10 via the second gate insulating film 16a, and the source electrode 23a and a drain electrode 23b provided on the interlayer insulating film 20 so as to be spaced apart from each other.

The semiconductor layer 15a is formed of a semiconductor film formed of an oxide semiconductor such as an In—Ga—Zn—O based semiconductor. As illustrated in FIG. 3, the semiconductor layer 15a includes a source region 15aa and a drain region 15ab that are defined to be spaced apart from each other, and a channel region 15ac that is defined between the source region 15aa and the drain region 15ab. Here, the In—Ga—Zn—O based semiconductor is ternary oxide of indium (In), gallium (Ga), and zinc (Zn), and a ratio (composition ratio) between In, Ga, and Zn is not particularly limited. In addition, the In—Ga—Zn—O based semiconductor may be an amorphous semiconductor or may be a crystalline semiconductor. Note that, as a crystalline In—Ga—Zn—O based semiconductor, a crystalline In—Ga—Zn—O based semiconductor in which the c-axis is oriented substantially perpendicular to the layer surface is preferable. In place of the In—Ga—Zn—O based semiconductor, another oxide semiconductor may be included. Examples of the other oxide semiconductor may include an In—Sn—Zn—O based semiconductor (for example, In₂O₃—SnO₂—ZnO; InSnZnO). Here, the In—Sn—Zn—O based semiconductor is ternary oxide of indium (In), tin (Sn), and zinc (Zn). Alternatively, examples of the other oxide semiconductor may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), cadmium zinc oxide (CdₓZn₁₋ₓO), and the like. Note that, as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, a semiconductor in a microcrystalline state in which the non-crystalline state and the polycrystalline state are mixed, or a semiconductor to which no impurity element is added can be used.

As illustrated in FIG. 3, the first gate electrode 13a is provided to overlap the semiconductor layer 15a, and is configured to control characteristics such as an S value (rise coefficient in a sub-threshold region) of the third TFT 9c.

Here, as illustrated in FIG. 3, the first gate electrode 13a is electrically connected to a wiring line layer 23e via a contact hole formed in the layered film of the first gate insulating film 14 and the interlayer insulating film 20. Note that the wiring line layer 23e, the source electrode 23a, the drain electrode 23b, and the wiring line layers 23c and 23d to be described below are formed of a first metal film, similar to the source line 23f and the like.

As illustrated in FIG. 3, the second gate electrode 19a is provided to overlap the channel region 15ac of the semiconductor layer 15a, and is configured to control the conduction between the source region 15aa and the drain region 15ab of the semiconductor layer 15a. Here, as illustrated in FIG. 3, the second gate electrode 19a is electrically connected to the wiring line layer 23c via a contact hole formed in the interlayer insulating film 20. Note that the second gate electrode 19a is formed of a fifth metal film, similar to the gate line 19g and the like.

As illustrated in FIG. 3, the source electrode 23a and the drain electrode 23b are electrically connected to the source region 15aa and the drain region 15ab of the semiconductor layer 15a, respectively, via contact holes formed in the interlayer insulating film 20.

Note that, in the present embodiment, the first TFT 9a, the second TFT 9b, and the third TFT 9c are illustrated as being of a double gate type, but the first TFT 9a, the second TFT 9b, and the third TFT 9c may be of a top gate type or a bottom gate type. Further, in the present embodiment, the first TFT 9a, the second TFT 9b, and the third TFT 9c are illustrated as being provided with the semiconductor layer 15a formed of an oxide semiconductor, but the semiconductor layer 15a may be formed of polysilicon such as low temperature polysilicon (LTPS). Furthermore, the TFT layer 30 may have a hybrid structure in which a TFT including a semiconductor layer formed of polysilicon and a TFT including a semiconductor layer formed of an oxide semiconductor are provided.

The capacitor 9d is electrically connected to the corresponding first TFT 9a and power supply line 23g in each of the subpixels P as illustrated in FIG. 5. In addition, as illustrated in FIG. 3, the capacitor 9d includes the first capacitance electrode 11c (formed of a third metal film), a second capacitance electrode 13b formed of a fourth metal film, and the base insulating film 12 provided between the first capacitance electrode 11c and the second capacitance electrode 13b. Here, the second capacitance electrode 13b is electrically connected to the wiring line layer 23d via a contact hole formed in the layered film of the first gate insulating film 14 and the interlayer insulating film 20, as illustrated in FIG. 3. Note that the wiring line layer 23d is electrically connected to the power supply line 23g.

The first flattening film 25a and the second flattening film 28a have a flat surface in the display region D, and are formed of, for example, an organic resin material such as a polyimide resin or an acrylic resin, or a polysiloxane-based spin on glass (SOG) material.

As illustrated in FIG. 3, the organic EL element layer 40 includes a plurality of reflective electrodes R, a common first edge cover 33a, a plurality of transparent electrodes 34a, a common second edge cover 35a, a plurality of organic EL layers 36, and a common light-transmissive electrode 37, which are layered in order corresponding to a plurality of subpixels P. Here, in each subpixel P, the reflective electrode R, the transparent electrode 34a, the organic EL layer 36, and the light-transmissive electrode 37 configure the organic EL element 39 as illustrated in FIG. 3, and in the organic EL element layer 40, a plurality of organic EL elements 39 provided corresponding to the plurality of subpixels P are disposed in a matrix.

A plurality of reflective electrodes R are provided in a matrix on the second flattening film 28a so as to correspond to the plurality of subpixels P. As illustrated in FIG. 3, the reflective electrodes R are electrically connected to the drain electrodes 23b of the third TFTs 9c via contact holes formed in the second flattening film 28a, the relay electrode 26a, and contact holes formed in the first flattening film 25a and the protection insulating film 24a. In addition, as illustrated in FIG. 3, the reflective electrodes R are provided by sequentially stacking a transparent conductive layer 31a and a metal layer 32a. Here, the transparent conductive layer 31a is formed of, for example, a transparent conductive film such as an indium tin oxide (hereinafter, also referred to as “ITO”) film and has light transmittance. In addition, the metal layer 32a is formed of a metal film such as a silver film or a silver alloy film and has light reflectivity.

The first edge cover 33a is provided in a lattice shape over the entire display region D, and is provided as a third inorganic insulating film so as to cover the circumferential end portion of the reflective electrode R, as illustrated in FIG. 3. Here, the first edge cover 33a is configured with, for example, an inorganic insulating film that is a single-layer film or a layered film of silicon nitride, silicon oxide, silicon oxynitride, or the like.

The transparent electrode 34a has a function of injecting holes into the organic EL layer 36. In addition, the transparent electrode 34a is preferably formed of a material having a high work function of improving the efficiency of hole injection into the organic EL layer 36. Here, the transparent electrode 34a is formed of, for example, a transparent conductive film such as an indium tin oxide (hereinafter, also referred to as “ITO”) film and has light transmittance.

The second edge cover 35a is provided in a lattice shape over the entire display region D, and is provided to cover the circumferential end portion of the transparent electrode 34a as illustrated in FIG. 3. Here, the second edge cover 35a is configured with, for example, an inorganic insulating film that is a single-layer film or a layered film of silicon nitride, silicon oxide, silicon oxynitride, or the like.

The organic EL layer 36 is provided as a light-emitting function layer and includes a hole injection layer 1, a hole transport layer 2, a light-emitting layer 3, an electron transport layer 4, and an electron injection layer 5 that are sequentially layered on the transparent electrode 34a, as illustrated in FIG. 6. Note that, in the present embodiment, a configuration in which each of the plurality of light-emitting function layers is the organic EL layer 36 has been exemplified, but at least one of the plurality of light-emitting function layers may be the organic EL layer 36.

The hole injection layer 1 is also referred to as an anode buffer layer, and has a function of reducing an energy level difference between the transparent electrode 34a and the organic EL layer 36 to improve the efficiency of hole injection from the transparent electrode 34a to the organic EL layer 36. Examples of the material configuring the hole injection layer 1 include polyarylalkane derivatives, pyrazoline derivatives, phenylenediamine derivatives, oxazole derivatives, styrylanthracene derivatives, fluorenone derivatives, hydrazone derivatives, stilbene derivatives, and the like.

The hole transport layer 2 has a function of improving the efficiency of hole transport from the transparent electrode 34a to the organic EL layer 36. Here, examples of the material configuring the hole transport layer 2 include triphenylamine derivatives, porphyrin derivatives, aromatic tertiary amine compounds, styrylamine derivatives, polyvinylcarbazole, poly-p-phenylenevinylene, polysilane, polyarylalkane derivatives, pyrazoline derivatives, pyrazolone derivatives, phenylenediamine derivatives, arylamine derivatives, amine-substituted chalcone derivatives, fluorenone derivatives, hydrazone derivatives, hydrogenated amorphous silicon, hydrogenated amorphous silicon carbide, zinc sulfide, zinc selenide, and the like.

The light-emitting layer 3 is a region into which holes and electrons are injected from the transparent electrode 34a and the light-transmissive electrode 37, respectively, when a voltage is applied by the transparent electrode 34a and the light-transmissive electrode 37, and in which the holes and electrons recombine. Here, the light-emitting layer 3 is formed of a material having high luminous efficiency. Moreover, examples of the material configuring the light-emitting layer 3 include metal oxinoid compounds (8-hydroxyquinoline metal complexes), naphthalene derivatives, anthracene derivatives, diphenylethylene derivatives, vinyl acetone derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, polysilane, and the like.

The electron transport layer 4 has a function of causing electrons to efficiently migrate to the light-emitting layer 3. Here, examples of the material configuring the electron transport layer 4 include imidazole derivatives, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, metal oxinoid compounds, and the like.

The electron injection layer 5 has a function of reducing an energy level difference between the light-transmissive electrode 37 and the organic EL layer 36 to improve the efficiency of electron injection from the light-transmissive electrode 37 into the organic EL layer 36, and this function can lower a drive voltage of the organic EL element 39. Note that the electron injection layer 5 is also referred to as a cathode buffer layer. Here, examples of the material configuring the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), strontium oxide (SrO), and the like.

The light-transmissive electrode 37 is provided on the plurality of organic EL layers 36 so as to be common to the plurality of subpixels P, that is, so as to cover each organic EL layer 36, the first edge cover 33a, and the second edge cover 35a, as illustrated in FIG. 3. The light-transmissive electrode 37 also has a function of injecting electrons into the organic EL layer 36. Further, the light-transmissive electrode 37 is preferably formed of a material having a low work function in order to improve the efficiency of electron injection into the organic EL layer 36. Here, the light-transmissive electrode 37 is formed of, for example, a transparent conductive film, such as an ITO film or an IZO film, or an extremely thin metal film such as an MgAg film, and has light transmittance.

As illustrated in FIG. 3, the sealing film 45 is provided to cover the light-transmissive electrode 37, includes a first inorganic sealing film 41, an organic sealing film 42, and a second inorganic sealing film 43 that are sequentially layered on the light-transmissive electrode 37, and has a function of protecting the organic EL layer 36 of the organic EL element 39 from moisture and oxygen.

The first inorganic sealing film 41 and the second inorganic sealing film 43 are configured with, for example, an inorganic insulating film such as a silicon nitride film, a silicon oxide film, or a silicon oxynitride film.

The organic sealing film 42 is formed of, for example, an organic resin material such as an acrylic resin, an epoxy resin, a silicone resin, a polyurea resin, a parylene resin, a polyimide resin, a polyamide resin, or the like.

The organic EL display device 50 also includes a plurality of first terminal layers 26t (see FIG. 4) formed of a second metal film and provided along the extension direction of the terminal portion T (Y direction in FIG. 1) in the terminal portion T in the frame region F. Here, as illustrated in FIG. 4, a first protection layer 27a and a first edge cover (second protection layer) 33a are provided on each first terminal layer 26t so as to expose a part of the first terminal layer 26t and cover the other part of the first terminal layer 26t.

Furthermore, as illustrated in FIG. 4, a second terminal layer 34t formed in the same layer and formed of the same material as the transparent electrode 34a is provided on the first terminal layer 26t exposed from the first protection layer 27a and the first edge cover 33a so as to cover the exposed first terminal layer 26. In addition, as illustrated in FIG. 4, a third terminal layer 23t formed of a first metal film is provided on the glass substrate 10 side of the first terminal layer 26t, and the first terminal layer 26t is provided to cover the third terminal layer 23t. Furthermore, as illustrated in FIG. 4, a fourth terminal layer 11t formed of a third metal film is provided on the glass substrate 10 side of the third terminal layer 23t, and the third terminal layer 23t is electrically connected to the fourth terminal layer 11t via contact holes formed in the base insulating film 12, the first gate insulating film 14, and the interlayer insulating film 20. The fourth terminal layer 11t is electrically connected to display wiring line such as the gate lines 19g, the light emission control lines 19e, the source lines 23f, and the power supply lines 23g.

In the organic EL display device 50 having the above-described configuration, in each of the subpixels P, the first TFT 9a is set to be in an on state by inputting a gate signal to the first TFT 9a via the gate line 19g. When a predetermined voltage corresponding to a source signal is written to a gate electrode of the second TFT 9b and the capacitor 9d via the source line 23f, and a light emission control signal is input to the third TFT 9c via the light emission control line 19e, the third TFT 9c is set to be in an on state. Then, by supplying a current corresponding to the gate voltage of the second TFT 9b from the power supply line 23g to the organic EL layer 36 of the organic EL element 39, the organic light-emitting layer 3 of the organic EL layer 36 emits light to display an image. Note that, in the organic EL display device 50, even when the first TFT 9a is set to be in an off state, the gate voltage of the second TFT 9b is held by the capacitor 9d, and thus light emission of the light-emitting layer 3 is maintained in each subpixel P until a gate signal of the next frame is input.

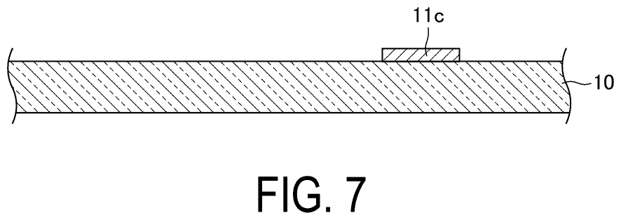

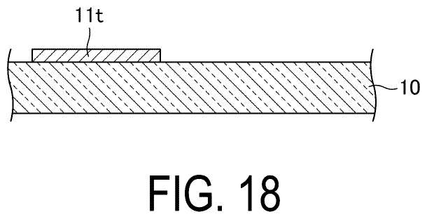

Next, a method of manufacturing the organic EL display device 50 according to the present embodiment will be described. Here, FIGS. 7 to 17 are first to eleventh cross-sectional views successively illustrating a part of a manufacturing process in the display region D of the organic EL display device 50, and are diagrams corresponding to FIG. 3. Furthermore, FIGS. 18 to 26 are first to ninth cross-sectional views successively illustrating a part of a manufacturing process in the terminal portion of the organic EL display device 50, and are diagrams corresponding to FIG. 4. Note that a method of manufacturing the organic EL display device 50 according to the present embodiment includes a TFT layer forming step, an organic EL element layer forming step, and a sealing film forming step.

### TFT Layer Forming Step

First, a copper film (approximately 300 nm thick) or the like is formed on the glass substrate 10, for example, by a sputtering method to form a third metal film, and then the third metal film is patterned to form the first capacitance electrode 11c, the fourth terminal layer 11t, and the like, as illustrated in FIGS. 7 and 18.

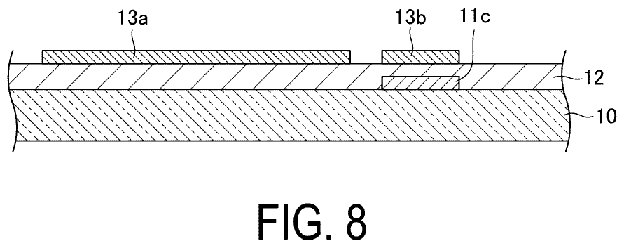

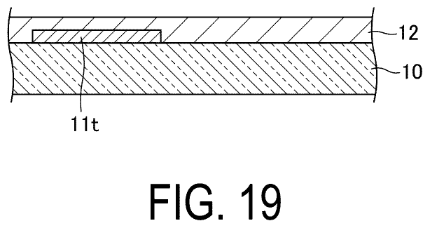

Subsequently, a silicon nitride film (approximately 150 nm thick) or the like is formed, for example, by a plasma chemical vapor deposition (CVD) method on the surface of the substrate on which the first capacitance electrode 11c and the like are formed, thereby forming the base insulating film 12 as a fourth inorganic insulating film (see FIGS. 8 and 19).

Thereafter, a copper film (approximately 300 nm thick) or the like is formed by a sputtering method on the surface of the substrate on which the base insulating film 12 is formed, thereby forming a fourth metal film. Then, the fourth metal film is patterned to form the first gate electrode 13a, the second capacitance electrode 13b, and the like, as illustrated in FIGS. 8 and 19.

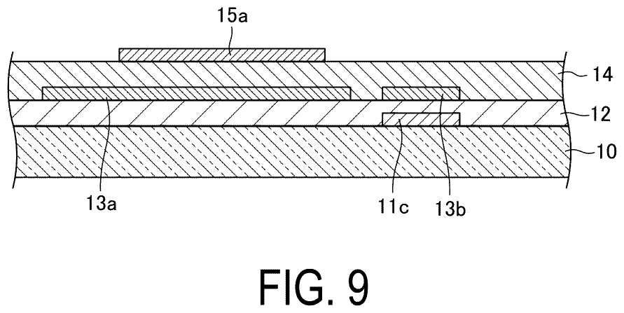

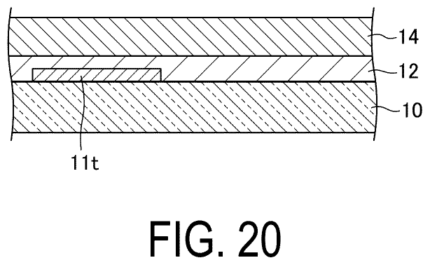

Furthermore, a silicon nitride film (approximately 100 nm thick) and a silicon oxide film (approximately 200 nm thick) are sequentially formed, for example, by a plasma CVD method on the surface of the substrate on which the first gate electrode 13a and the like are formed, thereby forming the first gate insulating film 14 as a fifth inorganic insulating film (see FIGS. 9 and 20).

Subsequently, a semiconductor film (approximately 50 nm thick) such as InGaZnO₄ is formed, for example, by a sputtering method on the surface of the substrate on which the first gate insulating film 14 is formed, and then the semiconductor film is patterned to form the semiconductor layers 15a and the like, as illustrated in FIGS. 9 and 20.

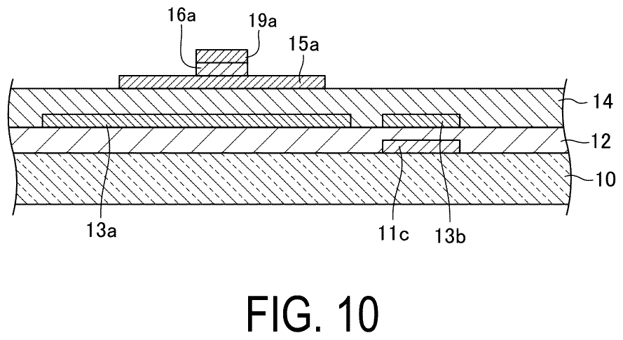

Thereafter, a silicon oxide film (approximately 200 nm thick) is formed, for example, by a plasma CVD method on the surface of the substrate on which the semiconductor layer 15a and the like are formed, and then a copper film (approximately 300 nm thick) is formed by a sputtering method to form a fifth metal film. Then, these layered films are patterned to form the second gate insulating film 16a as a sixth inorganic insulating film as illustrated in FIG. 10, and also form the second gate electrode 19a, the gate lines 19g, the light emission control lines 19e, and the like.

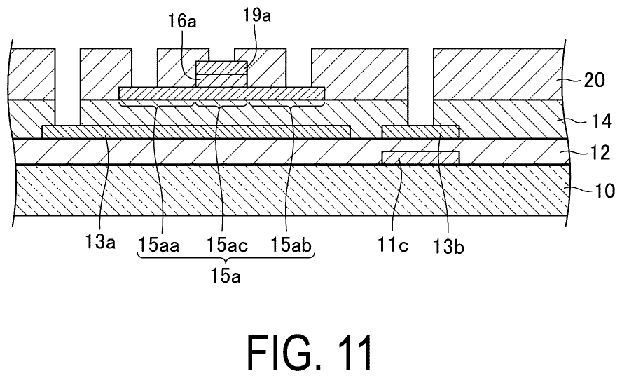

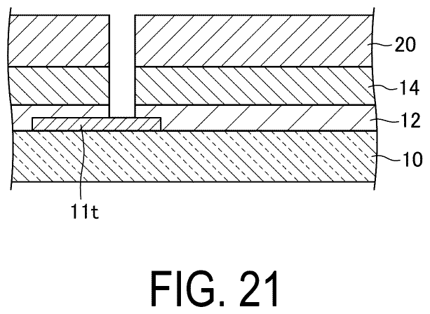

Furthermore, a silicon oxide film (approximately 300 nm thick) and a silicon nitride film (approximately 200 nm thick) are sequentially formed, for example, by a plasma CVD method on the surface of the substrate on which the second gate insulating film 16a and the like are formed. Then, these layered films, the first gate insulating film 14, and the base insulating film 12 are patterned to form contact holes, thereby forming the interlayer insulating film 20 as a seventh inorganic insulating film, as illustrated in FIGS. 11 and 21. Note that heat treatment performed when forming the interlayer insulating film 20 converts a part of the semiconductor layer 15a into a conductor, and the source region 15aa, the drain region 15ab, and the channel region 15ac are formed in the semiconductor layer 15a.

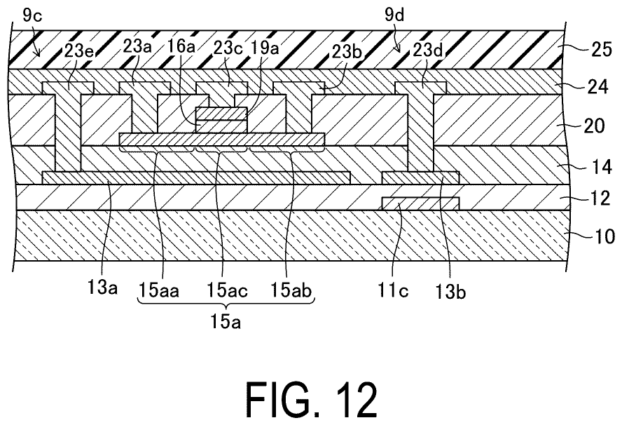

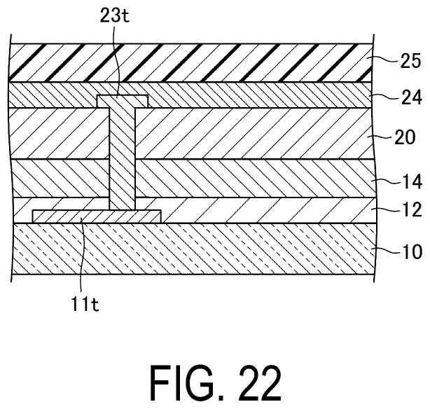

Subsequently, a copper film (approximately 300 nm thick) is formed, for example, by a sputtering method on the surface of the substrate on which the interlayer insulating film 20 is formed, thereby forming a first metal film. Then, the first metal film is patterned to form the source lines 23f, the power supply lines 23g, the source electrodes 23a, the drain electrodes 23b, the wiring line layers 23c, 23d, and 23e, the third terminal layer 23t, and the like (see FIGS. 12 and 22).

Thereafter, a silicon oxide film (approximately 150 nm thick) and a silicon nitride film (approximately 100 nm thick) are sequentially formed, for example, by a plasma CVD method on the surface of the substrate on which the source lines 23f and the like are formed, thereby forming the first inorganic insulating film 24. Then, as illustrated in FIGS. 12 and 22, a polyimide-based photosensitive resin film (approximately 2 μm thick) is applied, for example, by a spin coating method or a slit coating method to form a first organic insulating film 25.

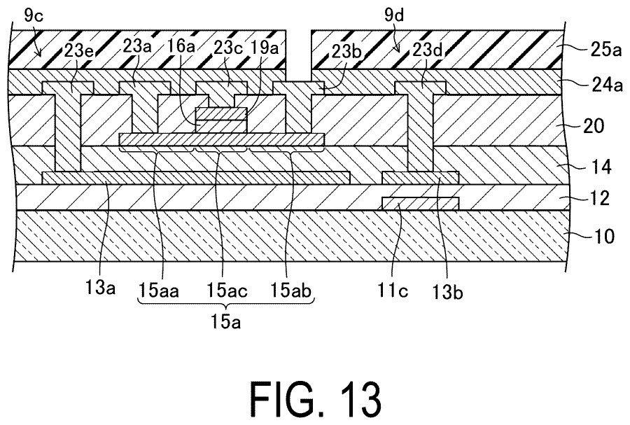

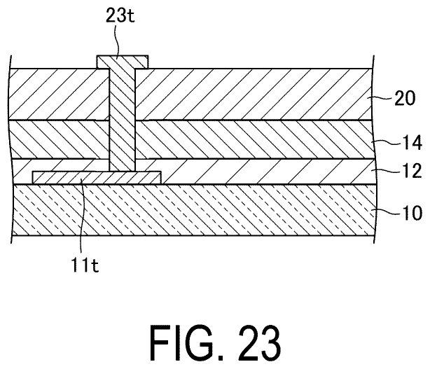

Furthermore, the first organic insulating film 25 is pre-baked, exposed, developed, and post-baked to form the first flattening film 25a as illustrated in FIGS. 13 and 23, and then the first inorganic insulating film 24 exposed from the first flattening film 25a is etched to form the protection insulating film 24a.

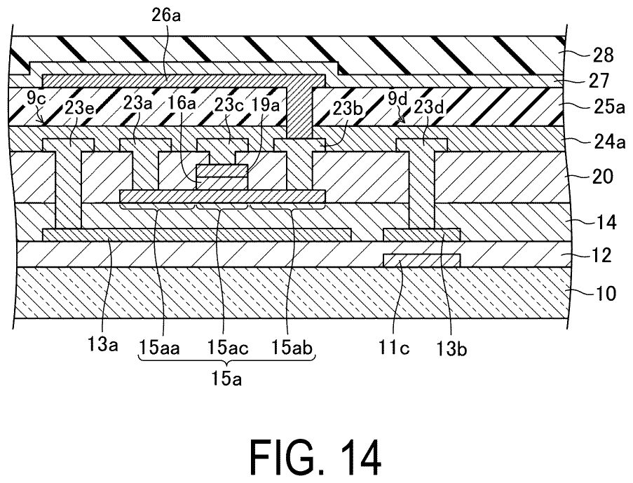

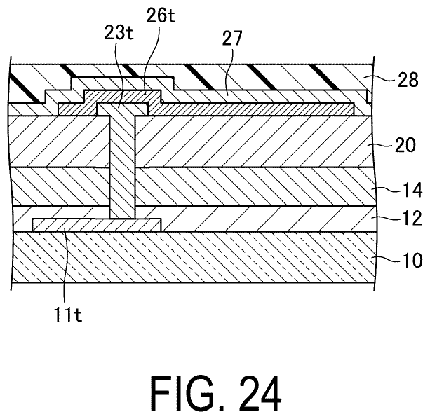

Subsequently, a copper film (approximately 300 nm thick) is formed, for example, by a sputtering method on the surface of the substrate on which the protection insulating film 24a is formed, thereby forming a second metal film. Then, the second metal film is patterned to form the relay electrode 26a, the first terminal layer 26t, and the like (see FIGS. 14 and 24).

Thereafter, a silicon nitride film (approximately 200 nm thick) is formed, for example, by a plasma CVD method on the surface of the substrate on which the relay electrodes 26a and the like are formed, thereby forming a second inorganic insulating film 27. Then, as illustrated in FIGS. 14 and 24, a polyimide-based photosensitive resin film (approximately 2 μm thick) is applied by a spin coating method or a slit coating method to form a second organic insulating film 28.

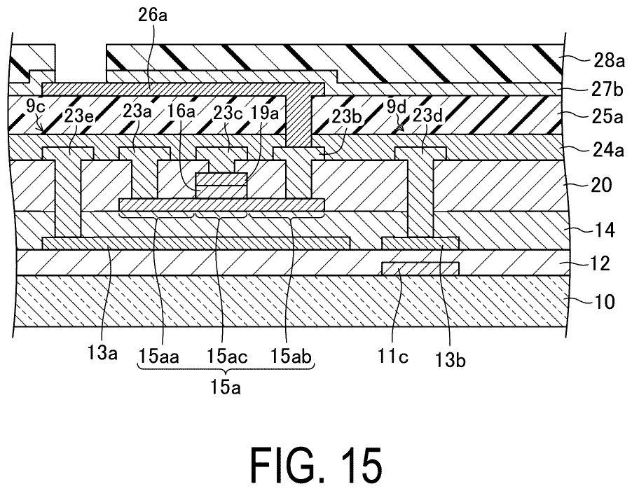

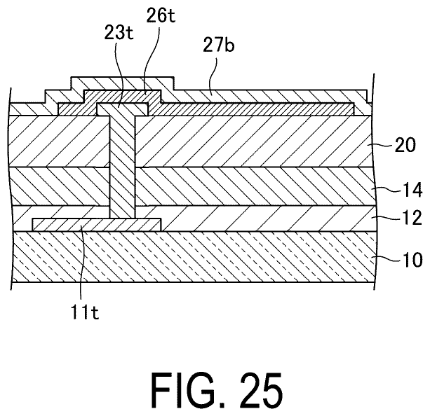

Finally, the second organic insulating film 28 is pre-baked, exposed, developed, and post-baked to form the second flattening film 28a, and then, as illustrated in FIGS. 15 and 25, the second inorganic insulating film 27 exposed from the second flattening film 28a is patterned to form a second inorganic insulating film 27b.

### Organic EL Element Layer Forming Step

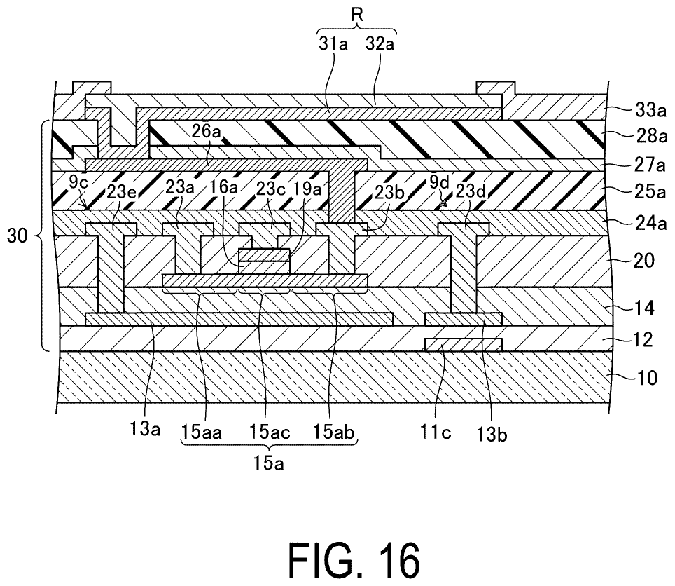

First, an ITO film (approximately 50 nm thick) and an Ag film (approximately 100 nm thick) are sequentially formed on the second flattening film 28a formed in the above-mentioned TFT layer forming step, for example, by a sputtering method, and then the layered films are patterned, for example, by wet etching using a mixture of phosphoric acid, nitric acid, and acetic acid to form a reflective electrode R configured with a transparent conductive layer 31a and a metal layer 32a, and the like (see FIG. 16).

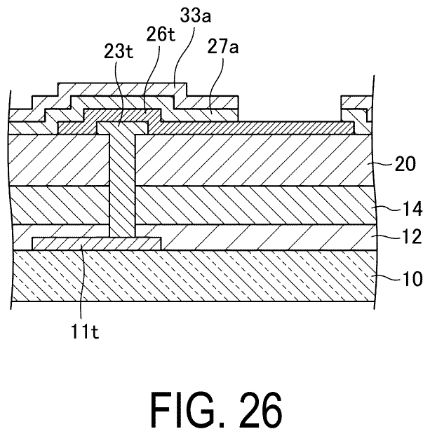

Subsequently, a silicon nitride film (approximately 100 nm thick) or the like is formed, for example, by a plasma CVD method on the surface of the substrate on which the reflective electrode R and the like are formed, thereby forming a third inorganic insulating film. Then, the third inorganic insulating film and the second inorganic insulating film 27b are patterned to form the first edge cover 33a and the first protection layer 27a, as illustrated in FIGS. 16 and 26.

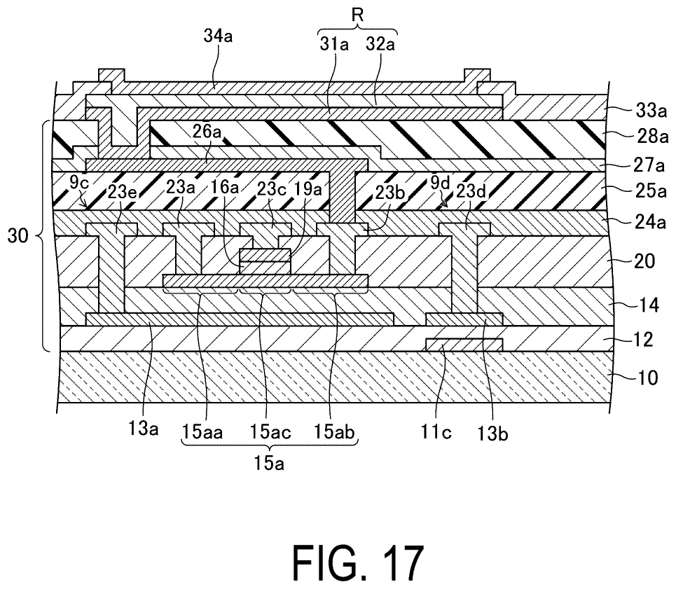

Thereafter, an ITO film (approximately 100 nm thick) is formed, for example, by a sputtering method on the surface of the substrate on which the first edge cover 33a and the like are formed. Then, the ITO film is patterned, for example, by wet etching using oxalic acid to form the transparent electrode 34a and a second terminal layer 34t (see FIG. 4) as illustrated in FIG. 17.

Furthermore, a silicon nitride film (approximately 250 nm thick) or the like is formed, for example, by a plasma CVD method on the surface of the substrate on which the transparent electrode 34a and the like are formed, and then the silicon nitride film and the like are patterned to form the second edge cover 35a.

Subsequently, the hole injection layer 1, the hole transport layer 2, the light-emitting layer 3, the electron transport layer 4, and the electron injection layer 5 are sequentially formed to a thickness of approximately several tens of nm to 50 nm on the surface of the substrate on which the second edge cover 35a is formed, for example, by a vacuum deposition method, thereby forming the organic EL layer 36.

Finally, a transparent conductive film such as an ITO film (approximately 100 nm thick) is formed by a sputtering method using a film forming mask on the surface of the substrate on which the organic EL layer 36 is formed, thereby forming the light-transmissive electrode 37.

As described above, the organic EL element layer 40 can be formed.

### Sealing Film Forming Step

First, an inorganic insulating film, such as a silicon nitride film, a silicon oxide film, or a silicon oxynitride film, is formed by a plasma CVD method using a film forming mask on the surface of the substrate on which the organic EL element layer 40 formed in the above-described organic EL element layer forming step is formed, thereby forming the first inorganic sealing film 41.

Subsequently, on the surface of the substrate on which the first inorganic sealing film 41 is formed, a film formed of an organic resin material such as acrylic resin is formed, for example, by using an ink-jet method, thereby forming the organic sealing film 42.

Finally, an inorganic insulating film such as a silicon nitride film, a silicon oxide film, or a silicon oxynitride film is formed by a plasma CVD method using a film forming mask on the surface of the substrate on which the organic sealing film 42 is formed, thereby forming the second inorganic sealing film 43 and thus forming the sealing film 45.

The organic EL display device 50 can be manufactured as described above.

As described above, according to the organic EL display device 50 of the present embodiment, the first protection layer 27a and the first edge cover 33a are provided on each first terminal layer 26t disposed in the terminal portion T so as to expose a part of the first terminal layer 26t and cover the other part of the first terminal layer 26t. Then, on the first terminal layer 26t exposed from the first protection layer 27a and the first edge cover 33a, the second terminal layer 34t formed in the same layer and formed of the same material as each transparent electrode 34a is provided to cover the first terminal layer 26t. Here, in the organic EL display device 50, even when the reflective electrode R is provided in the display region D, the terminal portion T is not provided with a conductive layer formed in the same layer and formed of the same material as the reflective electrode R, and thus it is possible to curb corrosion of the terminal portion T. Furthermore, in the organic EL element layer forming step, when the reflective electrode R is formed, the first terminal layer 26t is covered with the second inorganic insulating film 27b that serves as the first protection layer 27a, and thus it is possible to curb corrosion of the first terminal layer 26t and the third terminal layer 23t due to a mixture of phosphoric acid, nitric acid and acetic acid used when forming the reflective electrode R. Furthermore, since the first edge cover 33a is provided to cover the circumferential end portion of the reflective electrode R, it is possible to curb corrosion of the relay electrode 26a due to oxalic acid used when forming the transparent electrode 34a in the organic EL element layer forming step.

Furthermore, according to the organic EL display device 50 of the present embodiment, the second terminal layer 34t formed in the same layer and formed of the same material as each transparent electrode 34a is provided on the first terminal layer 26t exposed from the first protection layer 27a and the first edge cover 33a so as to cover the first terminal layer 26t, and thus it is possible to curb oxidation of the first terminal layer 26t.

### Other Embodiments

In the embodiment described above, an example of the organic EL layer having a five-layer structure including the hole injection layer, the hole transport layer, the light-emitting layer, the electron transport layer, and the electron injection layer has been described. However, the organic EL layer may have, for example, a three-layer structure including a hole injection-cum-transport layer, a light-emitting layer, and an electron transport-cum-injection layer.

Although the organic EL display device in which the electrode of the TFT connected to the first electrode serves as the drain electrode has been exemplified in each embodiment described above, the disclosure is also applicable to an organic EL display device in which an electrode of a TFT connected to a first electrode is referred to as a source electrode.

In each embodiment described above, the organic EL display device has been exemplified as the display device. The disclosure is also applicable to a display device including a plurality of light-emitting elements to be driven by a current, for example, to a display device including quantum dot light-emitting diodes (QLEDs), each of which is a light-emitting element using a quantum dot-containing layer.

### INDUSTRIAL APPLICABILITY

As described above, the disclosure is useful for self-luminous display devices.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. A display device comprising:
a base substrate;
a thin film transistor layer provided on the base substrate and configured such that a first metal film, a first inorganic insulating film, a first organic insulating film, a second metal film, a second inorganic insulating film, and a second organic insulating film are sequentially layered; and
a light-emitting element layer provided on the thin film transistor layer and configured such that a plurality of reflective electrodes, a common third inorganic insulating film, a plurality of transparent electrodes, a plurality of light-emitting function layers, and a common light-transmissive electrode are sequentially layered to correspond to a plurality of subpixels configuring a display region, the third inorganic insulating film being provided to cover circumferential end portions of the reflective electrodes, a frame region being provided around the display region, and a terminal portion being provided at an end of the frame region,
wherein the terminal portion is provided with a first terminal layer formed of the second metal film,
a first protection layer and a second protection layer formed of the second inorganic insulating film and the third inorganic insulating film are provided on the first terminal layer so as to expose a part of the first terminal layer and cover the other part of the first terminal layer, and
a second terminal layer formed in the same layer and formed of the same material as each of the transparent electrodes is provided on the first terminal layer exposed from the first protection layer and the second protection layer so as to cover the first terminal layer.

2. The display device according to claim 1,
wherein a third terminal layer formed of the first metal film is provided on the base substrate side of the first terminal layer, and
the first terminal layer is provided to cover the third terminal layer.

3. The display device according to claim 2,
wherein the thin film transistor layer is configured such that a third metal film, a fourth inorganic insulating film, a fourth metal film, a fifth inorganic insulating film, a semiconductor film, a sixth inorganic insulating film, a fifth metal film, a seventh inorganic insulating film, the first metal film, the first inorganic insulating film, the first organic insulating film, the second metal film, the second inorganic insulating film, and the second organic insulating film are sequentially layered on the base substrate, and
the thin film transistor layer is provided with a thin film transistor including a semiconductor layer having a source region and a drain region spaced apart from each other and a channel region between the source region and the drain region, the semiconductor layer being formed by the semiconductor film, a first gate electrode being provided on the base substrate side of the semiconductor layer via the fifth inorganic insulating film and formed of the fourth metal film, a second gate electrode being provided on the channel region via the sixth inorganic insulating film and formed of the fifth metal film, and a source electrode and a drain electrode being electrically connected to the source region and the drain region, respectively, and formed of the first metal film.

4. The display device according to claim 3,
wherein the semiconductor film is formed of an oxide semiconductor.

5. The display device according to claim 3,
wherein the thin film transistor layer is provided with a capacitor including a first capacitance electrode formed of the third metal film, a second capacitance electrode formed of the fourth metal film, and the fourth inorganic insulating film provided between the first capacitance electrode and the second capacitance electrode.

6. The display device according to claim 3,
wherein the terminal portion is provided with a fourth terminal layer formed of the third metal film, and
the third terminal layer is electrically connected to the fourth terminal layer.

7. The display device according to claim 1, further comprising:
a sealing film provided on the light-emitting element layer.

8. The display device according to claim 1,
wherein at least one of the plurality of light-emitting function layers is an organic electroluminescence layer.
